(19) United States
(12) Patent Application Publication
(10) Pub. No.: US 2026/0060022 A1
(43) Pub. Date: Feb. 26, 2026

(54) BONDED DIE STRUCTURES WITH REDUCED CRACK DEFECTS AND METHODS OF FORMING THE SAME

(71) Applicant: Taiwan Semiconductor Manufacturing Company Limited, Hsinchu (TW)

(72) Inventors: Jen-Yuan Chang, Hsinchu City (TW); Malvin Lin, Hsinchu City (TW); Wei-Lun Hsieh, Tainan City (TW); Chi-Yen Lin, Tainan City (TW)

(21) Appl. No.: 18/812,105

(22) Filed: Aug. 22, 2024

(51) Int. Cl. H01L 21/78; H01L 21/683; H01L 23/00; H01L 23/544; H01L 23/58; H01L 25/065

(52) U.S. Cl. CPC H01L 21/78; H01L 21/6835; H01L 23/544; H01L 23/562; H01L 23/585; H01L 24/05; H01L 24/81; H01L 25/0657; H01L 2221/68327; H01L 2223/54426; H01L 2224/05647; H01L 2224/81894; H01L 2225/06562; H01L 2924/3512

(57) ABSTRACT

Bonded die structures and methods of fabricating bonded die structures with improved stress distribution. A bonded die structure may include a second die bonded to a first die. The sizes, shapes and/or relative position of the first die with respect to the second die may be configured to minimize stress concentrations in the bonded die structure. In some embodiments, a length dimension of a corner region of the second die may be less than a length dimension of the adjacent corner region of the first die, which may aid in redistributing stress away from the corner of the first die. An offset distance between the corner of the second die and the corner of the first die may also be controlled to minimize stress applied to the corner of the first die along a vertical direction. Accordingly, crack formation may be reduced, and device performance and yields may be improved.

### BACKGROUND

The semiconductor industry has grown due to continuous improvements in integration density of various electronic components (e.g., transistors, diodes, resistors, capacitors, etc.).

In addition to smaller electronic components, improvements to the packaging of components have been developed in an effort to provide smaller packages that occupy less area than previous packages. Example approaches include quad flat pack (QFP), pin grid array (PGA), ball grid array (BGA), flip chips (FC), three-dimensional integrated circuits (3DICs), wafer level packages (WLPs), package on package (PoP), System on Chip (SoC) or System on Integrated Circuit (SoIC) devices. Some of these three-dimensional devices are prepared by placing chips over chips. These three-dimensional devices provide improved integration density and other advantages because of the decreased length of interconnects between the stacked chips. However, there are many challenges related to three-dimensional devices.

### BRIEF DESCRIPTION OF THE DRAWINGS

Aspects of this disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a vertical cross-sectional view illustrating a first die disposed on a first carrier structure according to various embodiments of the present disclosure.

FIG. 1B is a top view of the first die illustrating the shape of the first die according to various embodiments of the present disclosure.

FIG. 2 is a vertical cross-section view illustrating a first dielectric material laterally surrounding the first die according to various embodiments of the present disclosure.

FIG. 3 is a vertical cross-section view illustrating a first bonding layer formed over the first dielectric material and the first die according to various embodiments of the present disclosure.

FIG. 4 is a vertical cross-section view illustrating a bonded structure including a plurality of second dies disposed over and bonded to the first die according to various embodiments of the present disclosure.

FIG. 5 is a vertical cross-section view of a bonded structure illustrating a second dielectric material laterally surrounding each of the second dies according to various embodiments of the present disclosure.

FIG. 6 is a vertical cross-section view of a bonded structure disposed on a second carrier structure according to various embodiments of the present disclosure.

FIG. 7 is a vertical cross-section view of a bonded die structure according to various embodiments of the present disclosure.

FIG. 8 is a vertical cross-section view of a bonded die structure including a plurality of solder balls over the front side of the first die according to various embodiments of the present disclosure.

FIG. 9 is a vertical cross-section view showing the bonded die structure mounted on a support structure via a plurality of solder balls according to various embodiments of the present disclosure.

FIG. 10A is a top view of a corner region of a first die according to various embodiments of the present disclosure.

FIG. 10B is a top view of a corner region of a second die according to various embodiments of the present disclosure.

FIG. 10C is a top view of corner regions of a bonded structure including a first die and a second die bonded to the first die according to various embodiments of the present disclosure.

FIG. 10D is a vertical cross section view of the bonded structure taken along line A-A′ in FIG. 10C.

FIG. 10E is a vertical cross section view of the bonded structure taken along line B-B′ in FIG. 10C.

FIG. 10F is a top view of a bonded die structure illustrating the corner region of the first die surrounded by gap fill dielectric material according to various embodiments of the present disclosure.

FIG. 10G is a vertical cross-section view of a portion of the bonded die structure of FIG. 10F including the corner regions of the first and second dies according to various embodiments of the present disclosure.

FIG. 11A is a vertical cross-section view of a bonded die structure in accordance with various embodiments of the present disclosure.

FIG. 11B is a top view illustrating the bonded die structure of FIG. 11A.

FIG. 12A is a vertical cross-section view of a bonded die structure in accordance with various embodiments of the present disclosure.

FIG. 12B is a top view illustrating the bonded die structure of FIG. 12A.

FIG. 13A is a vertical cross-section view of a bonded die structure in accordance with various embodiments of the present disclosure.

FIG. 13B is a top view illustrating the bonded die structure of FIG. 13A.

FIG. 14A is a vertical cross-section view of a bonded die structure in accordance with various embodiments of the present disclosure.

FIG. 14B is a top view illustrating the bonded die structure of FIG. 14A

FIG. 15A is a top view of a corner region of a first die according to another embodiment of the present disclosure.

FIG. 15B is a top view of a corner region of a second die according to various embodiments of the present disclosure.

FIG. 15C is a top view illustrating corner regions of a bonded structure including a second die as shown in FIG. 15B bonded to a first die as shown in FIG. 15A according to various embodiments of the present disclosure.

FIG. 16A is a top view of a corner region of a first die according to another embodiment of the present disclosure.

FIG. 16B is a top view of a corner region of a second die according to another embodiment of the present disclosure.

FIG. 16C is a top view illustrating corner regions of a bonded structure including a second die as shown in FIG. 16B bonded to a first die as shown in FIG. 16A according to various embodiments of the present disclosure.

FIG. 17 is a flowchart illustrating a method of fabricating a bonded die structure according to various embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

Various embodiments disclosed herein are directed to semiconductor devices, and specifically to bonded die structures that include a plurality of semiconductor dies bonded to one another. The bonded semiconductor dies may be in a configuration such as a system on integrated chip (SoIC), chip on wafer on substrate (CoWoS), chip on wafer (CoW), etc. Such bonded die structures may increase the density of devices that may occupy a given planar area or “footprint.”

Semiconductor integrated circuits may include a semiconductor material substrate, such as a silicon substrate, having a number of circuit components and elements formed on and/or within the semiconductor material. Semiconductor integrated circuits are typically fabricated by sequentially depositing insulating or dielectric layers, conductive layers, and semiconductive layers of material over the semiconductor substrate (e.g., a wafer), and patterning the various material layers using lithography to form integrated circuits. Portions of the semiconductor substrate containing separate integrated circuits thereon may then be separated (i.e., singulated) from the remainder of the semiconductor substrate via a dicing process to provide individual semiconductor dies

A bonded structure may be formed by placing a second die onto a first die and performing a bonding process to bond the second die to the first die. In some embodiments, a direct bonding technique, such as metal-to-metal (M-M) and dielectric-to-dielectric (D-D) bonding techniques, may be used to bond the dies to form the bonded structure. Other types of bonding processes, such as a fusion bonding process between dielectric bonding material layers, may also be utilized.

In some embodiments, a dielectric material, which may also be referred to as a gap fill dielectric material, may be formed around each of the dies of the bonded structure. In some embodiments, a dicing process may be used to separate portions of the bonded structure to form individual bonded die structures, where each bonded die structure may include a stack of two or more semiconductor dies that are bonded together. The dicing process may be performed around the periphery of the bonded dies through the gap fill dielectric material and a carrier structure (e.g., a wafer or substrate) to which the bonded dies may be attached.

In some cases, the fabrication processes used to form the bonded die structure may result in stress on various components of the bonded die structure. The stress may be due, in part, to different material properties, such as differences in thermal expansion coefficients (also coefficient of thermal expansion, CTE), between different materials in the bonded die structure. Excessive stress may result in cracking or other damage to various components, including the dies.

Various embodiments include bonded die structures and methods of fabricating bonded die structures with improved stress distribution that may inhibit the formation of cracks and other stress-induced defects. In various embodiments, a bonded die structure may include a second die bonded to a first die. The sizes, shapes and/or relative positioning of the first die with respect to the second die may be configured to minimize stress concentrations in the bonded die structure. In some embodiments, a length dimension of a corner region of the second die may be less than a length dimension of the adjacent corner region of the first die. This may help redistribute stress from the surrounding gap fill dielectric material away from the corner region of the first die, which may aid in reducing the occurrence of crack defects in the first die. In further embodiments, an offset distance between the corner of the second die and the corner of the first die may be controlled to minimize the stress applied to the corner of the first die along a vertical direction. This may further aid in reducing cracking of the first die. Accordingly, device performance and yields may be improved.

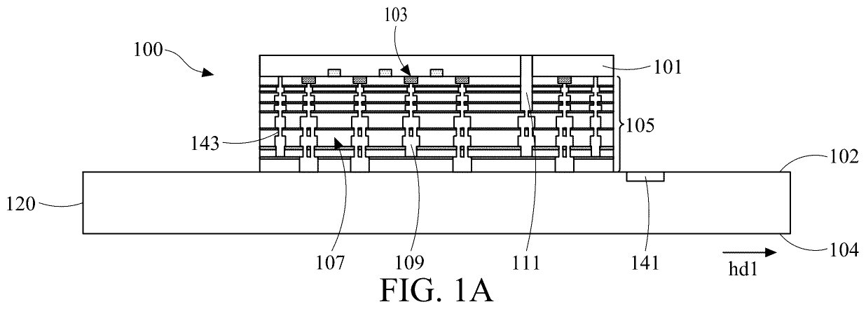

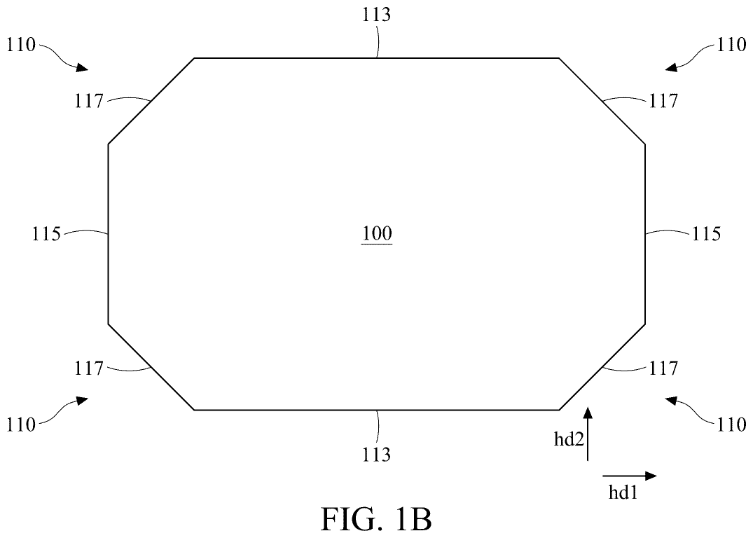

FIG. 1A is a vertical cross-sectional view illustrating a first die 100 disposed on a first carrier structure 120 and adhered by an adhesive (not shown) according to various embodiments of the present disclosure. The first carrier structure 120 may include a suitable substrate (e.g., a semiconductor substrate, an organic substrate, a glass substrate, a ceramic substrate, etc.) that may be configured to support one or more semiconductor dies. In one non-limiting embodiment, the first carrier structure 120 may include a semiconductor (e.g., silicon) wafer. The first carrier structure 120 may include a first (i.e., front) side 102 and a second (i.e., back) side 104. In various embodiments, the first carrier structure 120 may optionally include at least one alignment mark 141 disposed on and/or within the first carrier structure 120. The at least one alignment mark 141 may include discreate features (e.g., geometric shape(s) or patterns) that may be detectable visually and/or via the use of an optical detection system. The at least one alignment mark 141 may function as a reference or guide as to the precise placement of dies 100 onto the front side 102 of the first carrier structure 120.

Referring again to FIG. 1A, the first die 100 may include a first semiconductor substrate 101 that may include an elementary semiconductor such as silicon or germanium and/or a compound semiconductor such as silicon germanium, silicon carbide, gallium arsenic, indium arsenide, gallium nitride, or indium phosphide, or combinations of the same. Other semiconductor substrate materials are within the contemplated scope of disclosure. In some embodiments, the first semiconductor substrate 101 may be a semiconductor-on-insulator (SOI) substrate. In some embodiments, a plurality of first devices 103 may be disposed on, over and/or in the first semiconductor substrate 101. The first devices 103 may include, for example, active devices, passive devices, or a combination thereof. In some embodiments, the first devices 103 disposed on, over and/or in the first semiconductor substrate 101 may include integrated circuit devices. The integrated circuit devices may include, for example, transistors (e.g., field-effect transistors (FETs), capacitors, resistors, diodes, photodiodes, fuse devices, or other similar devices. In some embodiments, the integrated circuit devices may include gate electrodes, source/drain regions, spacers, isolation trenches, and the like.

The first die 100 may additionally include a first interconnect structure 105 over the first semiconductor substrate 101. The first interconnect structure 105 may include metal interconnect features 109 (e.g., metal lines, vias and/or bonding pads) within a dielectric material 107 (e.g., one or more inter-layer dielectric (ILD) layers and/or inter-metal dielectric (IMD) layers) that may provide connections to and/or between various first devices 103 located on, over and/or in the first semiconductor substrate 101. The first interconnect structure 105 may optionally also include one or more first seal rings 143 that may extend around the periphery of the first die 100. The one or more first seal rings 143 may help to provide protection to the device structures of the first die 100 against electrical interference, mechanical damage and/or contamination. In some embodiments, the one or more first seal rings 143 may include a metallic material (e.g., copper, nickel, aluminum, etc.) embedded in the dielectric material 107 of the first interconnect structure 105. In some embodiments, the first die 100 may also include one or more first through-substrate vias (TSVs) 111 extending through the first semiconductor substrate 101. The first TSVs 111 may provide electrical connections through the first semiconductor substrate 101 to the first devices 103 and/or metal interconnect features 109 of the first interconnect structure 105 of the first die 100.

Referring again to FIG. 1A, the first die 100 may be placed onto the front side 102 of the first carrier structure 120 using a suitable placement apparatus, such as a pick-and-place tool. The at least one alignment mark 141 may be utilized as a guide to aid in placement of the first die 100 in the correct location on the first carrier structure 120.

In some embodiments, a plurality of first dies 100 may be placed in predetermined locations over the front side 102 of the first carrier structure 120. Alignment marks 141 may optionally be utilized to ensure proper alignment and registration of the respective first dies 100. In some embodiments, the first dies 100 may be adhered to the front side 102 of the first carrier structure 120 using a suitable adhesive (not shown in FIG. 1A). In some embodiments, the adhesive may include a material that may be subsequently treated to cause the adhesive to lose its adhesive properties, such that the first carrier structure 120 may be separated from the first dies 100. In some embodiments, the adhesive may lose its adhesive properties when subjected to treatment using an energy source, such as a thermal, optical (e.g., UV, IR, laser, etc.) and/or sonic (e.g., ultrasonic) energy source. Alternatively, the adhesive may include a material, such as an acrylic pressure-sensitive adhesive material, that may decompose when subjected to an elevated temperature. Other suitable adhesive materials are within the contemplated scope of disclosure.

In the embodiment shown in FIG. 1A, the first die 100 is shown placed onto the front side 102 of the first carrier structure 120 in a “face down” configuration such that a front side of the first die 100 (i.e., the side adjacent to the first interconnect structure 105) faces towards the first carrier structure 120 and a back side of the first die 100 (i.e., the side adjacent to the first semiconductor substrate 101) faces away from the first carrier structure 130. However, it will be understood that in other embodiments, the first die 100 may be placed in a “face up” configuration where the back side of the first die 100 may face towards the first carrier structure 120 and the front side of the first die 100 may face away from the first carrier structure 120.

FIG. 1B is a top view of the first die 100 illustrating the shape of the first die 100 according to various embodiments of the present disclosure. Referring to FIG. 1B, the first die 100 may include a pair of first sides 113 extending parallel to one another along a first horizontal direction hd1 and a pair of second sides 115 extending parallel to one another along a second horizontal direction hd2. Corner sides 117 extend between a first side 113 and a second side 115 in each corner region 110 of the first die 100. In the embodiment of FIG. 1B, the periphery of the first die 100 has a truncated quadrilateral shape. However, it will be understood that other suitable shapes for the first die 100 are within the contemplated scope of disclosure.

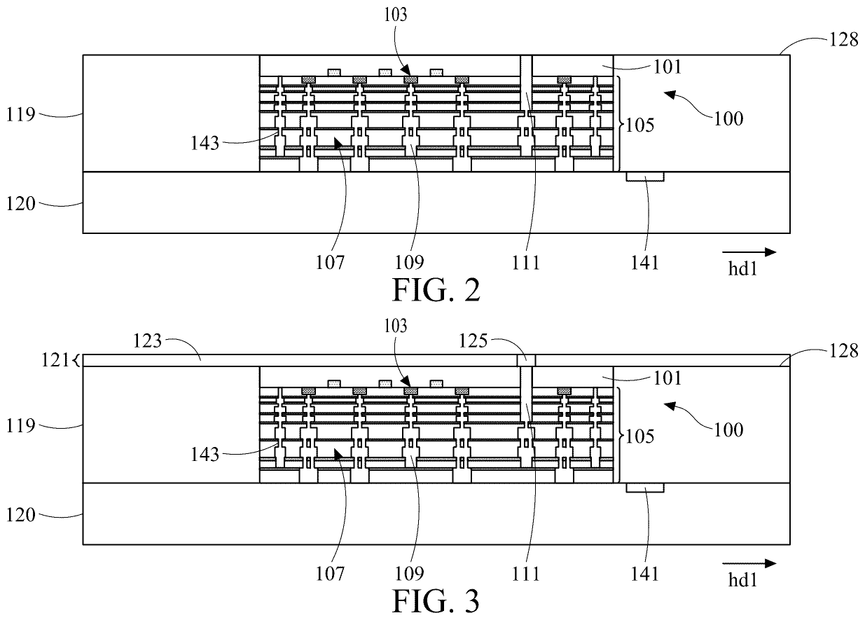

FIG. 2 is a vertical cross-section view illustrating a first dielectric material 119 laterally surrounding the first die 100 according to various embodiments of the present disclosure. Referring to FIG. 2, a first dielectric material 119 may be deposited over the front side 102 of the first carrier structure 120 and the first die 100. The first dielectric material 119 may include a suitable dielectric material, such as silicon oxide, silicon nitride, silicon carbide, silicon oxynitride, silicon carbon nitride, a low-K dielectric material, and extremely low-K (ELK) dielectric material, undoped silicon glass (USG), fluorosilicate glass (FSG), phosphor-silicate glass (PSG), etc., including combinations thereof. Other suitable dielectric materials for the first dielectric material 119 are within the contemplated scope of disclosure. The first dielectric material 119 may be deposited using a suitable deposition process, such as chemical vapor deposition (CVD) process, a physical vapor deposition (PVD) process, an atomic layer deposition (ALD) process, a high density plasma CVD (HDPCVD) process, a low pressure CVD process, a metalorganic CVD (MOCVD) process, a plasma enhanced CVD (PECVD) process, a sputtering process, laser ablation, or the like. In some embodiments, the first dielectric material 119 may be deposited over the front side 102 of the first carrier structure 120 and over side surfaces and an upper surface of the first die 100, and a planarization process, such as a chemical mechanical planarization (CMP) process, may be used to remove excess dielectric material from over the first die 100 to provide a first dielectric material 119 laterally surrounding the first die 100. The upper surface of the first dielectric material 119 and the back side of the first die 100 may form a continuous planar surface 128. In embodiments in which multiple first dies 100 are disposed over the front side 102 of the first carrier structure 120, the first dielectric material 119 may extend between each of the first dies 100 and may also be referred to as a first gap fill dielectric material 119.

FIG. 3 is a vertical cross-section view illustrating a first bonding layer 121 formed over the first dielectric material 119 and the first die 100 according to various embodiments of the present disclosure. Referring to FIG. 3, a first bonding layer 121 may be formed over the continuous planar surface 128 formed by the upper surface of the first dielectric material 119 and the back side of the first die 100. In various embodiments, the first bonding layer 121 may be formed by depositing a first dielectric layer 123 over the continuous planar surface 128 formed by the upper surface of the first dielectric material 119 and the back side of the first die 100. The first dielectric layer 123 may include silicon oxide, silicon nitride, silicon carbide, silicon carbon nitride, silicon oxynitride, a dielectric polymer material, or the like, including various combinations thereof. Other suitable dielectric materials are within the contemplated scope of disclosure. The first dielectric layer 123 may be formed using a suitable deposition process as described above. In some embodiments, a planarization process, such as a CMP process, may be used to provide a planar upper surface of the first dielectric layer 123.

Referring again to FIG. 3, one or more metal features (e.g., bonding pads, vias, etc.) may be formed in the first dielectric layer 123 of the first bonding layer 121. The one or more metal features may include a suitable conductive material, such as copper (Cu), tungsten (W), aluminum (Al), and the like. The one or more metal features may be formed in the first dielectric layer 123 via a damascene or dual-damascene process, for example. FIG. 3 illustrates a first bonding pad 125 formed within the first dielectric layer 123. It will be understood that a plurality of first bonding pads 125 as shown in FIG. 3 may be formed within the first dielectric layer 123 of the first bonding pad 121. At least some of the first bonding pads 125 may be electrically coupled to a TSVs 111 of the underlying first semiconductor substrate 101 of the first die 100.

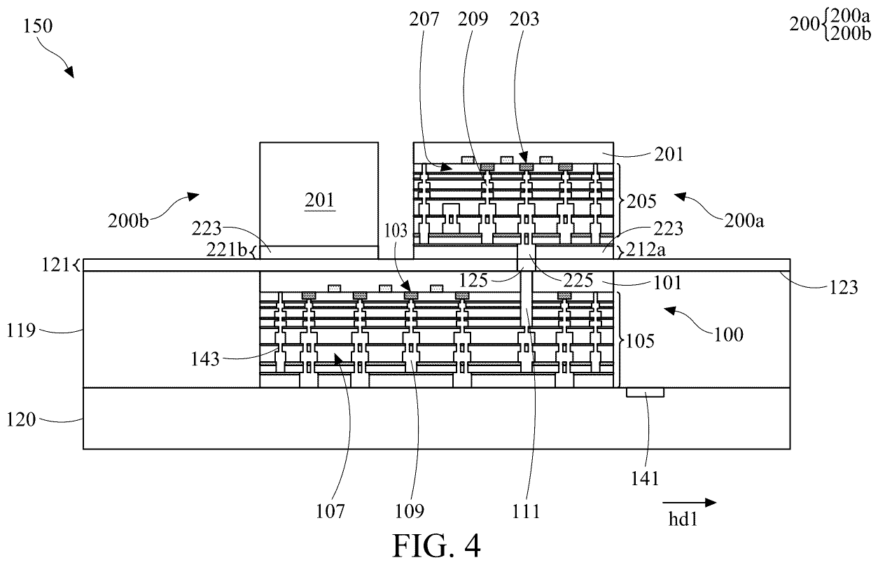

FIG. 4 is a vertical cross-section view illustrating a bonded structure 150 including a plurality of second dies 200 disposed over and bonded to the first die 100 according to various embodiments of the present disclosure. Referring to FIG. 4, the plurality of second dies 200 may include a first second die 200a and a second die 200b. The first second die 200a may be similar to the first die 100 as described above with reference to FIG. 2. The first second die 200a may include a second semiconductor substrate 201. A plurality of second devices 203 may be disposed on, over and/or in the second semiconductor substrate 201. The first second die 200a may additionally include a second interconnect structure 205 over the second semiconductor substrate 201. The second interconnect structure 205 may include metal interconnect features 209 within a dielectric material 207 as described above. The second interconnect structure 205 may optionally also include one or more second seal rings 243.

Referring again to FIG. 4, a first second bonding layer 221a may be formed over the second interconnect structure 205 of the first second die 200a. The first second bonding layer 221a may be similar to the first bonding layer 121 described above with reference to FIG. 3. The first second bonding layer 221a may include one or more metal features (e.g., second bonding pads 225) embedded in a second dielectric material 223. The arrangement of the second bonding pads 225 in the first second bonding layer 221a may correspond to the arrangement of corresponding first bonding pads 125 in the first bonding layer 121. At least some of the second bonding pads 225 may be electrically coupled to metal interconnect features 209 of the second interconnect structure 205 of the first second die 200a.

A bonding process may be utilized to bond the first second bonding layer 221a and the first bonding layer 121 and thereby bond the first second die 200a to the first die 100. In some embodiments, the first second bonding layer 221a may be bonded to the first bonding layer 121 via a metal-to-metal (M-M) and dielectric-to-dielectric (D-D) direct bonding technique to couple the first second die 200a mechanically and electrically to the first die 100. In some embodiments, prior to bonding the first second die 200a to the first die 100, the surfaces of the first bonding layer 121 on the first die 100 and/or the first second bonding layer 221a on the first second die 200a may optionally be subjected to a pre-treatment process (e.g., a plasma treatment process) to promote surface activation of the first bonding layer 121 and/or the first second bonding layer 221a prior to bonding the first second die 200a to the first die 100.

Referring again to FIG. 4, the first second die 200a may be placed onto the first die 100 (e.g., using a pick-and-place tool) such that the first second bonding layer 221a may contact the first bonding layer 121. The first second die 200a may be aligned over the first die 100 such that first bonding pads 125 of the first bonding layer 121 of the first die 100 may be aligned with and may contact corresponding second bonding pads 225 of the first second bonding layer 221a of the first second die 200a. In some embodiments, one or more above-described alignment marks 141 may be used to aid in the proper positioning and placement of the first second die 200a.

In a direct bonding process, such as a metal-to-metal (M-M) and dielectric-to-dielectric (D-D) bonding process, bringing the first bonding layer 121 and the first second bonding layer 221a into contact with one another may result in a pre-bonding process in which chemical bonds (e.g., hydrogen bridge bonds) may form at the planar interface between the dielectric material 123 of the first bonding layer 121 and the dielectric material 223 of the first second bonding layer 221a. In some embodiments, the pre-bonding process may be performed at ambient temperature (e.g., ˜20°C). In other embodiments, the pre-bonding process may be performed at an elevated temperature. In some embodiments, a compressive force may be applied to the first second die 200a and the first die 100 during the pre-bonding process. In other embodiments, no compressive force may be applied during the pre-bonding process.

Referring again to FIG. 4, in some embodiments, an annealing process may be performed to complete the bonding of the first bonding pads 125 of the first bonding layer 121 to the second bonding pads 225 of the first second bonding layer 221a according to various embodiments of the present disclosure. The annealing process may be performed at an elevated temperature, such as 100° C. or more, such as between about 150° C. and about 350° C., although lower and higher temperatures may also be utilized. In some embodiments, a compressive force may be applied to the first second die 200a and the first die 100 during the annealing process. In other embodiments, no compressive force may be applied during the annealing process.

Following the bonding process, the first second die 200a may be mechanically and electrically coupled to the first die 100. The first second die 200a and the first die 100 may each include any type of die, including a functional die, such as a logic die (e.g., a CPU die, a GPU die, an ASIC die, etc.), a memory die (e.g., an SRAM die, an HBM die, etc.), an analog die, an RF die, an integrated passive device (IPD) die, a deep trench capacitor (DTC) die, etc., including various combinations thereof. In other embodiments, one or both of the first second die 200a and the first die 100 may be a non-functional or “dummy” die that may provide in-line process structure uniformity and/or routing of electrical signals.

In the embodiment of FIG. 4, the first second die 200a may be bonded to the first die 100 in a “front-to-back” configuration in which the front side of the first second die 200a (i.e., the side adjacent to the second interconnect structure 205) is bonded to the back side of the first die 100 (i.e., the side adjacent to the first semiconductor substrate 101). However, it will be understood that other embodiments the first second die 200a may be bonded to the first die 100 in a different configuration, such as a “back-to-front” configuration, a “front-to-front” configuration, or a “back-to-back” configuration. Further, although a metal-to-metal (M-M) and dielectric-to-dielectric (D-D) direct bonding process is described herein, it will be understood that other bonding processes, such as a fusion bonding process, a microbump bonding process, etc., may be used to bond the first die 100 and the first second die 200a.

Referring again to FIG. 4, a second die 200b may also be disposed over and bonded to the first die 100 according to various embodiments of the present disclosure. In the embodiment of FIG. 4, the second die 200b may be a non-functional “dummy” die. The second die 200b may include a second semiconductor substrate 201. In some embodiments, a dielectric material and optionally metal interconnect structures may be disposed over the second semiconductor substrate 201 of the second die 200b. However, the second die 200b may lack above-described devices 103, 203 formed on, over and/or in the second semiconductor substrate 201. As discussed above, a non-functional or “dummy” die 200b as shown in FIG. 4 may be utilized for in-line process structure uniformity and/or for routing of electrical signals. In other embodiments, the second die 200b may be a functional die as described above.

A second bonding layer 221b may be formed on the second die 200b. The second bonding layer 221b may include a second dielectric material 223. In some embodiments, the second bonding layer 221b may not include metal features, such as bonding pads, in the second dielectric material 223. In some embodiments, the region of the first bonding layer 121 onto which the second die 200b is to be placed may similarly lack first bonding pads 125.

The second die 200b may be placed onto the first die 100 (e.g., using a pick-and-place tool). In some embodiments, one or more above-described alignment marks 141 may be used to aid in the proper positioning and placement of the second second die 200b onto a desired location on the first die 100. A bonding process may then be utilized to bond the second bonding layer 221b and the first bonding layer 121 and thereby bond the second die 200b to the first die 100. In some embodiments, the second bonding layer 221b may be bonded to the first bonding layer 121 via a fusion bonding process. The fusion bonding process may include a room-temperature pre-bonding stage where hydrogen bonds may create initial interface bonds between the second dielectric material 223 of the second bonding layer 221b and the first dielectric material 123 of the first bonding layer 121. Additionally, the fusion bonding process may include a high-temperature annealing stage where an annealing process facilitates formation of covalent bonds on the surfaces of the respective bonding layers 121, 221b. Other types of bonding processes, such as an M-M and D-D direct bonding process, a microbump bonding process, etc., may be utilized to bond the second die 200b to the first die 100. Following the bonding process, the second die 200a may be mechanically and optionally electrically coupled to the first die 100. The second dies 200a and 200b bonded to the first die 100 may be laterally separated from one another.

Although the bonded structure 150 of FIG. 4 includes a pair of second dies 200 bonded to the first die 100, it will be understood that a single second die 200, or more than two second dies 200, may be bonded to the first die 100 in various embodiments. The second dies 200 may include functional dies, non-functional “dummy” dies, or various combinations of the same. In embodiments in which multiple first dies 100 are disposed on the first carrier structure 120, one or more second dies 200 may be bonded to each of the first dies 100.

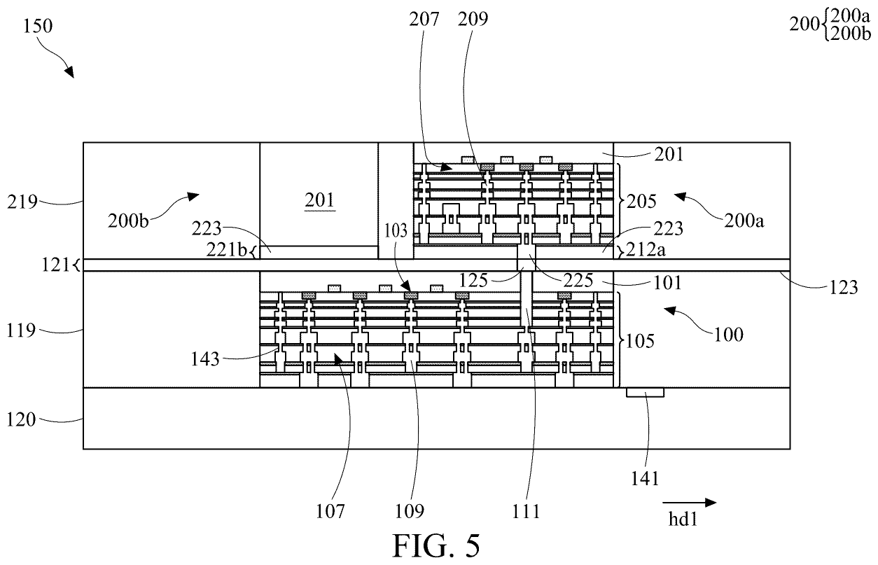

FIG. 5 is a vertical cross-section view of a bonded structure 150 illustrating a second dielectric material 219 laterally surrounding each of the second dies 200 according to various embodiments of the present disclosure. Referring again to FIG. 5, a second dielectric material 219 may be deposited over the first bonding layer 121 and each of the second dies 200. The second dielectric material 119 may be similar or identical to the first dielectric material 119 described above with reference to FIG. 2. Thus, repeated discussion of like features is omitted for brevity. In some embodiments, the second dielectric material 119 may be deposited over the first bonding layer 121 and over the side surfaces and upper surface of each of the second dies 200, including within the gap(s) between adjacent second dies 200. A planarization process, such as a chemical mechanical planarization (CMP) process, may be used to remove excess dielectric material from over the upper surface of the second dies 200 to provide a second dielectric material 219 laterally surrounding the second dies 200. The upper surfaces of the second dies 200 may be substantially coplanar with the upper surface of the second dielectric material 219 in some embodiments. The second dielectric material 219 may fill the gaps between adjacent second dies 200 and may also be referred to as a second gap fill dielectric material 219. The first dielectric material 119 and the second dielectric material 219 may collectively be referred to as a gap fill dielectric material 119, 219.

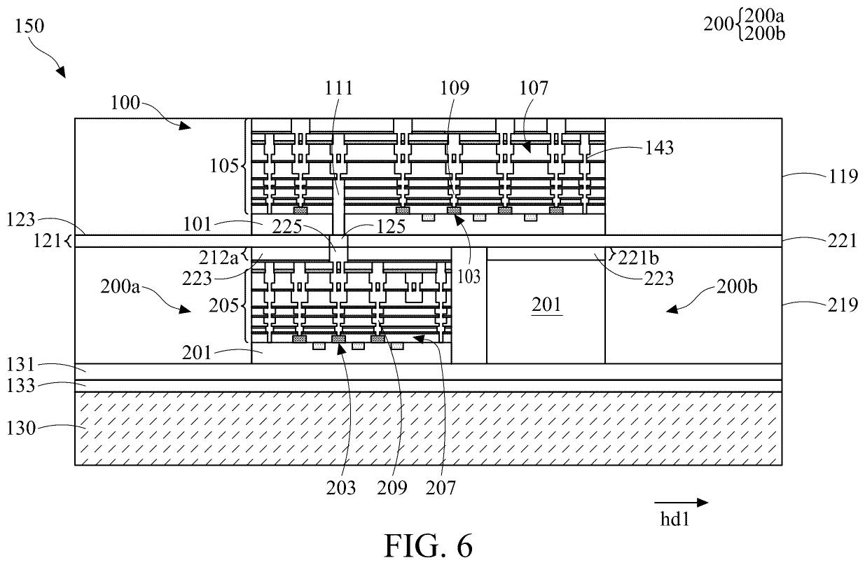

FIG. 6 is a vertical cross-section view of a bonded structure 150 disposed on a second carrier structure 130 according to various embodiments of the present disclosure. Referring to FIG. 6, second carrier structure 130 may include a suitable substrate (e.g., a semiconductor substrate, an organic substrate, a glass substrate, a ceramic substrate, etc.) that may be configured to support the bonded structure 150. In one non-limiting embodiment, the second carrier structure 130 may include a semiconductor (e.g., silicon) wafer.

In some embodiments, the second carrier structure 130 may be bonded to the bonded structure 150 using a fusion bonding technique. A bonding layer 131 including a dielectric material may be formed over the second dielectric material 219 and the second dies and another bonding layer 133 including a dielectric material may be formed over a surface of the second carrier structure 130. A fusion bonding process as described above with reference to FIG. 5 may be utilized to bond the bonding layers 131 and 133 and thereby bond the second carrier structure 130 to the bonded structure 150. Other suitable techniques for bonding the second carrier structure 130 to the bonded structure 150 are within the contemplated scope of disclosure. For example, the second carrier structure 130 may be bonded to the bonded structure 150 using a suitable adhesive, such as a glue.

Referring again to FIG. 6, the first carrier structure 120 may be removed from the bonded structure 150 using a suitable technique. In some embodiments, this may include subjecting an adhesive material that bonds the first carrier structure 120 to the bonded structure 150 to a treatment, such a thermal treatment, a radiation treatment, etc., that causes the adhesive material to lose its adhesive properties and then separating the first carrier structure 120 from the bonded structure 150. Other suitable techniques for removing the first carrier structure 120 are within the contemplated scope of disclosure. The first carrier structure 120 may be removed from the bonded structure 150 either before or after the second carrier structure 130 is attached to the bonded structure 150. Thus, the bonded structure may be effectively transferred from the first carrier structure 120 to the second carrier structure 130. The orientation of the bonded structure 150 may be inverted (i.e., flipped over) relative to the orientation shown in FIG. 5 such that the bonded structure 150 may be supported on the second carrier structure 130 with the first die 100 located over the second dies 200.

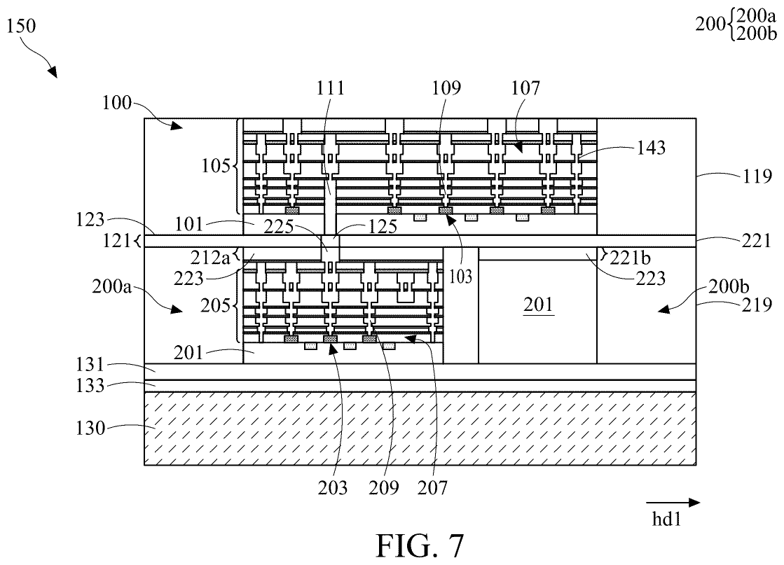

FIG. 7 is a vertical cross-section view of a bonded die structure 160 according to various embodiments of the present disclosure. In various embodiments, the structure shown in FIG. 6 may be subjected to a dicing process. The dicing process may include a mechanical dicing process that utilizes a blade, such as a diamond or carbide blade, to cut (e.g., saw) through the gap fill dielectric material 119, 219 and the second carrier structure 130 to provide one or more individual bonded die structures 160 as shown in FIG. 7. Other dicing techniques, such as plasma dicing, laser grooving, etc., may also be utilized. The bonded die structure 160 may include a plurality of second dies 200 located over a second carrier structure 130 and a first die 100 located over and bonded to the second dies 200. The gap fill dielectric material 119, 219 may laterally surround the first die 100 and the second dies 200 and may fill the gap(s) between the second dies 200.

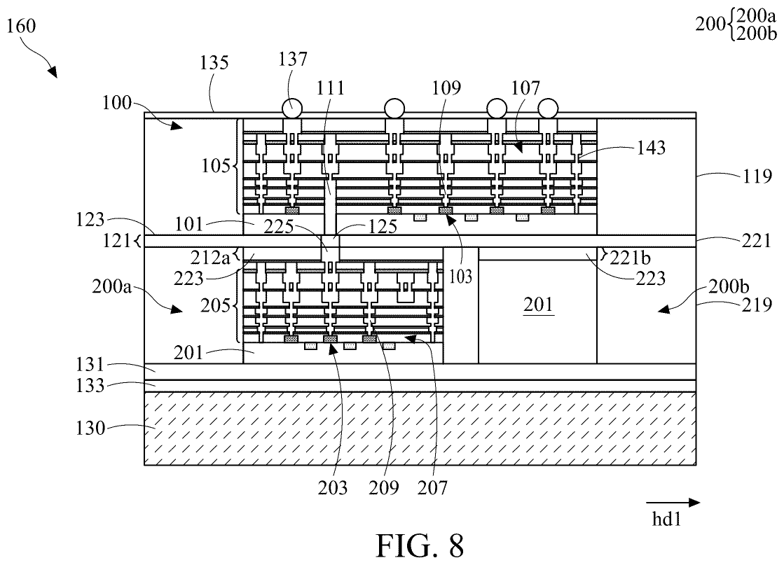

FIG. 8 is a vertical cross-section view of a bonded die structure 160 including a plurality of solder balls 137 over the front side of the first die 100 according to various embodiments of the present disclosure. Referring to FIG. 8, a dielectric material 135 may be formed over the first dielectric material 119 and the front side of the first die 100. The dielectric material 135 may include a plurality of openings, where a metal feature (e.g., a bonding pad) may be exposed through each of the openings. The metal features may include, or may be electrically coupled to, metal features 109 of the underlying first interconnect structure 105 of the first die 100. A plurality of solder balls 137 may be provided, where each solder ball 137 may contact a metal feature exposed through the openings in the dielectric material 135.

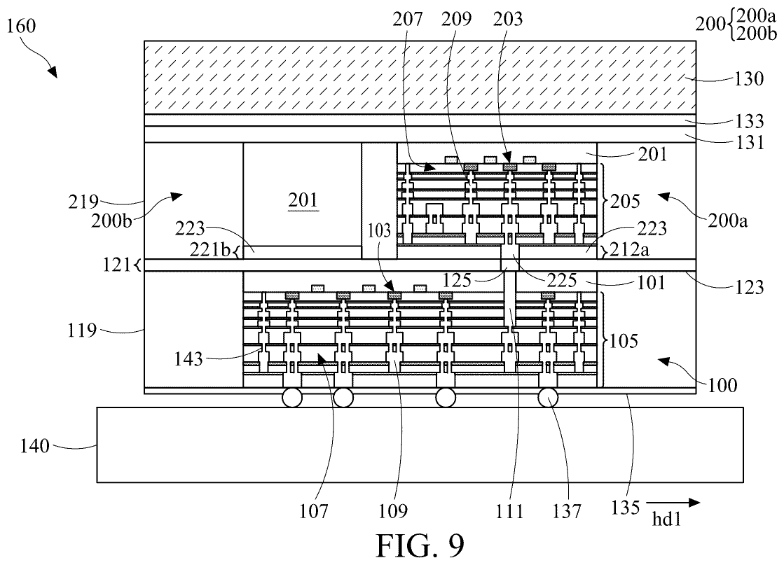

FIG. 9 is a vertical cross-section view showing the bonded die structure 160 mounted on a support structure 140 via a plurality of solder balls 137 according to various embodiments of the present disclosure. Referring to FIG. 9, the bonded die structure 160 may be inverted (i.e., flipped over) relative to its orientation as shown in FIG. 8 such that the front side of the first die 100 faces downwards and the back side of the second carrier structure 130 faces upwards. The bonded die structure 160 may be aligned over a support structure 140. The support structure 140 may include, for example, a semiconductor wafer, an interposer, and/or a substrate (e.g., a semiconductor, a glass, or an organic substrate) that may be configured to support the bonded die structure 160. The bonded die structure 160 may be brought into contact with the support structure 140 such that the solder balls 137 may contact corresponding bonding structures (e.g., bonding pads) on the surface of the support structure 140. A reflow process may be used to bond the bonded die structure 160 to the support structure 160.

The fabrication process used to form a bonded die structure 160 such as shown in FIG. 9 may result in internal stress in the bonded die structure 160. The internal stress may be due, in part, to different material properties, such as differences in thermal expansion coefficients, between different materials in the bonded die structure 160. In some cases, stress may be concentrated on the first die 100, and in particular, in the corner regions 110 of the first die 100 that may be subjected to thermally-induced stress from the gap fill dielectric material 119, 219 along at least four directions (i.e., three lateral directions and a vertical direction). Excessive stress accumulation in the corner regions 110 of the first die 100 may result in cracking or other damage to the first die 100, which may result in defective bonded die structures 160 and reduced yields.

Various embodiments include bonded die structures 160 and methods of fabricating bonded die structures 160 with improved stress distribution that may inhibit the formation of cracks and other stress-induced defects. In various embodiments, a bonded die structure 160 may include a second die 200 bonded to a first die 100, where a length dimension of a corner region of the second die 200 may be less than a length dimension of the adjacent corner region of the first die 100. This may help redistribute stress from the surrounding gap fill dielectric material away from the corner region of the first die 100, which may aid in reducing the occurrence of crack defects in the first die.

In some embodiments, first and second sides of the second die 200 located adjacent to the corner region of the second die may not extend beyond the corresponding first and second sides of the first die located adjacent to the corner region of the first die, and in some cases one or both of the first and second sides of the second die may be laterally offset with respect to the corresponding first and second sides of the first die. In some embodiments, an offset distance between a corner side of the second die 200 and a corresponding corner side of the first die 100 may be equal to or less than the offset distance between the first side of the second die and the first side of the first die and/or the offset distance between the second side of the second die and the second side of the first die. In some embodiments, the offset distance between the corner side of the second die 200 and the corner side of the first die 100 may be between about 70% and about 90% of the first side of the second die and the first side of the first die and/or the offset distance between the second side of the second die and the second side of the first die. Such a configuration may help to minimize the stress applied on the corner region of the first die along a vertical direction, which may further aid in reducing cracking of the first die. Accordingly, device performance and yields may be improved.

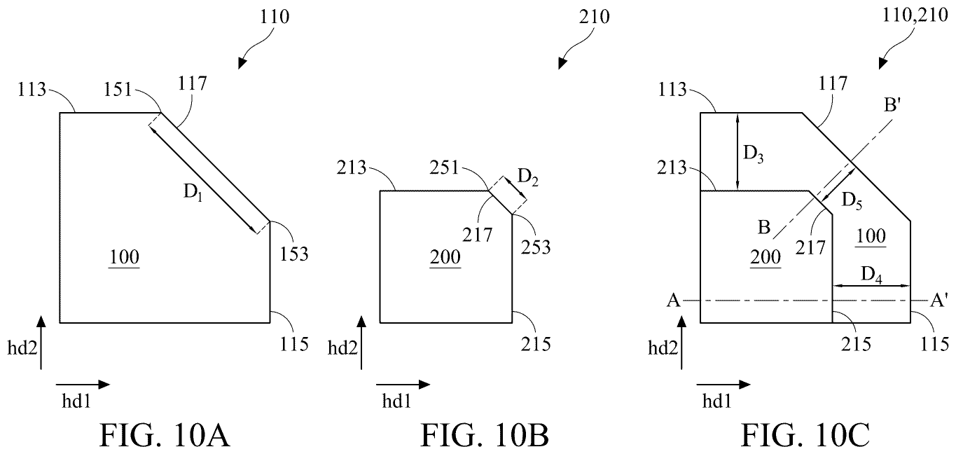

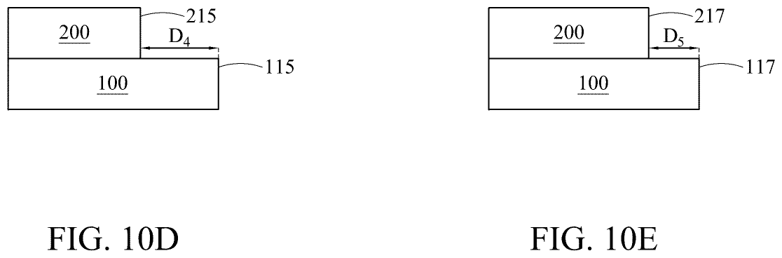

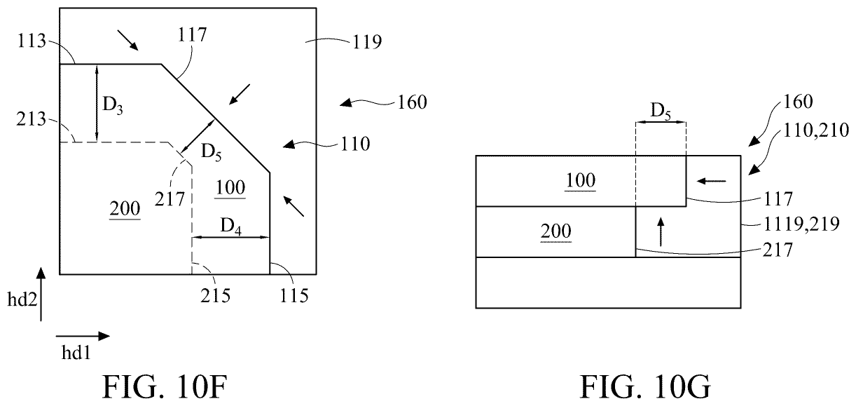

FIG. 10A is a top view of a corner region 110 of a first die 100 according to various embodiments of the present disclosure. FIG. 10B is a top view of a corner region 210 of a second die 200 according to various embodiments of the present disclosure. Referring to FIGS. 10A and 10B, in various embodiments, the corner regions 210 of the second dies 200 (e.g., a logic die 200a or a dummy die 200b as described above) in a bonded die structure 160 may have a similar shape as the corresponding corner regions 110 of the first die 100 to which the second dies 200 are bonded. As discussed above, the first die 100 may have a truncated quadrilateral shape including first sides 113 extending along a first horizontal direction hd1 and second sides 115 extending along a second horizontal direction hd2 and corner sides 117 extending in a diagonal direction between a first side 113 and a second side 115 in each corner region 110 of the first die 100. In various embodiments, at least one of the corner regions 210 of each second die 200 that is bonded to the first die 100 may have a similar shape, including a first side 213 extending along the first horizontal direction hd1, a second side 115 extending along a second horizontal direction hd2, and a corner side 217 extending in a diagonal direction between the first side 213 and the second side 215, as shown in FIG. 10B. In some embodiments, each corner region 210 of the second dies 200 that is located adjacent to a corner region 110 of the first die 100 may have a shape as shown in FIG. 10B. In some embodiments, all of the corner regions 210 of the one or more of the second dies 200 may have a shape as shown in FIG. 10B.

In various embodiments, the corner regions 110 of the first die 110 may differ from the adjacent corner regions 210 of the second die(s) 200 in that a length dimension D₁ of each of the corner regions 110 of the first die 100 may be greater than a length dimension D₂ of the corresponding corner region 210 of the second die(s) 200. As used herein, the length dimension D₁ of a corner region 110 of the first die 100 may be equal to the length of a line segment extending between the end point 151 of the first side 113 of the first die 100 that is located adjacent to the corner region 110 to the end point 153 of the second side 115 of the first die 100 that is located adjacent to the corner region 110. In the embodiment shown in FIG. 10A, the corner side 117 of the corner region 110 extends in a straight line between the end point 151 of the first side 113 and the end point 153 of the second side 115. Thus, the length dimension D₁ of the corner region 110 in this embodiment is equal to the length of the corner side 117 of the first die 110. In other embodiments, such as described in further detail below, the corner side 117 may not extend linearly between the respective end points 151 and 153, and thus the length dimension D₁ of the corner region 110 may not necessarily be equal to the length of the corner side 117 of the first die 100.

Similarly, the length dimension D₂ of the corner region 210 of the second die 200 that is adjacent to the first die 100 may be equal to the length of a line segment extending between the end point 251 of the first side 213 of the second die 200 that is located adjacent to the corner region 210 to the end point 253 of the second side 215 of the second die 200 that is located adjacent to the corner region 210.

In various embodiments, the length dimension D₁ of the corner region 110 of the first die 100 may be greater than the length dimension D₂ of the adjacent corner region 210 of the second die 200. As discussed in further detail below, providing corner regions 110 of the first die 100 having greater length dimensions D₁ than the length dimensions D₂ of the corresponding corner regions 210 of the second die(s) 200 may help to distribute stress away from the corner regions 110 of the first die 100, thereby reducing stress concentration on the corner regions 110 of the first die 100 and minimizing the occurrence of crack defects in the first die 100.

FIG. 10C is a top view of corner regions 110, 210 of a bonded structure 150 including a first die 100 and a second die 200 bonded to the first die 100 according to various embodiments of the present disclosure. FIG. 10D is a vertical cross section view of the bonded structure 150 taken along line A-A′ in FIG. 10C. FIG. 10E is a vertical cross section view of the bonded structure 150 taken along line B-B′ in FIG. 10C. The second die 200 in the embodiment of FIGS. 10C-10E may be a first second die 200a (e.g., a logic die) or a second die 200b (e.g., a dummy die) as described above. Referring to FIG. 10C, in some embodiments, the second die 200 may not extend beyond the sides of the first die—i.e., the second die 200 may not overhang the first side 113 or the second side 115 of the first die 100. It has been found that where the second die 200 extends beyond the sides 113, 213 of the first die 100, there is a risk that the second die 200 may interfere with the die saw during the above-described dicing process (see FIG. 7) that is used to form the bonded die structure 160. This can result in damage to the bonded die structures 160 and reduce device yields.

In some cases, the second die 200 may be placed onto the first die 100 such that one or both of first side 213 or second side 215 of the second die 200 may be vertically aligned with the corresponding first side 113 or second side 115 of the first die 100. However, due to imprecision in the precise placement of the second die 200 onto the first die 100, it may be beneficial to provide a lateral offset between the respective sides 213 and 215 of the second die 200 and the corresponding sides 113 and 115 of the first die 100 in order to avoid the above-described problem of die saw interference.

In the embodiment shown in FIGS. 10C-10E, the first side 213 of the second die 200 may be laterally offset from the adjacent first side 113 of the first die 100 by an offset distance D₃. The offset distance D₃ may be ≥0, and in various embodiments may be >0. The second side 215 of the second die 200 may be laterally offset from the adjacent second side 115 of the first die 100 by an offset distance D₄. The offset distance D₄ may be ≥0, and in various embodiments may be >0. The corner side 217 of the second die 200 may be laterally offset from the adjacent corner side 117 of the first die 100 by an offset distance D₅. In various embodiments, D₅ may be less than or equal to D₃ and/or D₅ may be less than or equal to D₄. In some embodiments, D₅ may be less than both D₃ and D₄. In one non-limiting embodiment, the offset distance D₅ between the corner side 217 of the second die 200 and the corner side 117 of the first die 100 may be between about 70% and about 90% of the offset distance D₃ between the first side 213 of the second die 200 and the first side 113 of the first die 100. Alternatively, or in addition, the offset distance D₅ between the corner side 217 of the second die 200 and the corner side 117 of the first die 100 may be between about 70% and about 90% of the offset distance D₄ between the second side 215 of the second die 200 and the second side 115 of the first die 100.

In various embodiments, by providing corner regions 110 of the first die 100 having greater length dimensions D₁ than the corresponding length dimensions D₂ of the corner sides 217 of the second die(s) 200, and by providing an offset distance D₅ between the respective corner sides 117 and 217 that is less than or equal to the offset distances D₃ and D₅ between the first sides 113 and 213 and the second sides 115 and 215 of the first die 100 and the second die 200, stress may be more effectively distributed around the corner region 110 of the first die 100, which may reduce the occurrence of crack defects in the first die 100. This is schematically illustrated in FIGS. 10F and 10G. FIG. 10F is a top view of a bonded die structure 160 illustrating the corner region 110 of the first die 100 surrounded by gap fill dielectric material 119 according to various embodiments of the present disclosure. FIG. 10F illustrates the underlying second die 200 and the locations of the first side 213, second side 215 and corner side 217 of the second die 200 in dashed lines. FIG. 10G is a vertical cross-section view of a portion of the bonded die structure 160 of FIG. 10F including the corner regions 110 and 210 of the first and second dies 100 and 200. Referring to FIGS. 10F and 10G, differences in the thermal expansion coefficient between material(s) of the first die 100 (e.g., silicon) and the surrounding gap fill dielectric material 119, 219 (e.g., SiO₂, SiN, etc.) may result in thermally-induced mechanical stress on the first die 100. This stress is schematically illustrated by the arrows in FIG. 10F which illustrate the lateral stresses that may be applied to the corner region 110 of the first die 100. These stresses may be applied to the corner region 110 along three different directions surrounding the first die 100, as shown in FIG. 10. Additional stress may also be applied in a vertical direction. This is schematically illustrated by the vertical arrow in the cross-section view of FIG. 10G, which shows the stress applied to the corner region 110 of the first die 100 along a vertically upwards direction. These stresses as schematically shown in FIGS. 10F and 10G may result in cracking of the first die 100, particularly within the corner regions 110 of the first die 100. Furthermore, it has been found that the larger the volume of the gap fill dielectric material 119, 219 underlying the corner region 110 of the first die 100, the greater the magnitude of the stress applied along a vertical direction, as shown in FIG. 5G, and the higher the likelihood of excessive stress accumulation resulting in crack defects occurring in this region.

In various embodiments, by providing a relatively small offset distance D₅ between the corner side 217 of the second die 200 and the corner side 117 of the first die 100, such as an offset distance D₅ that is less than or equal to the offset distances D₃ and D₄ between the first sides 113, 213 of the dies 100, 200 and the second sides 115, 117 of the dies 100, 200, a relatively lower volume of the gap fill dielectric material 119, 219 may be present underlying the corner region 110 of the first die 100. Accordingly, the stress on the first die 100 along a vertical direction may be more evenly distributed between the corner region 110 and along the sides 113, 115 of the first die 100, which may minimize the accumulation of stress on the corner region 110 and thereby reduce the risk of crack formation in the first die 100. In some embodiments, improved stress balance may be achieved when D₅ is between about 70% and about 90% of D₃ and/or D₄.

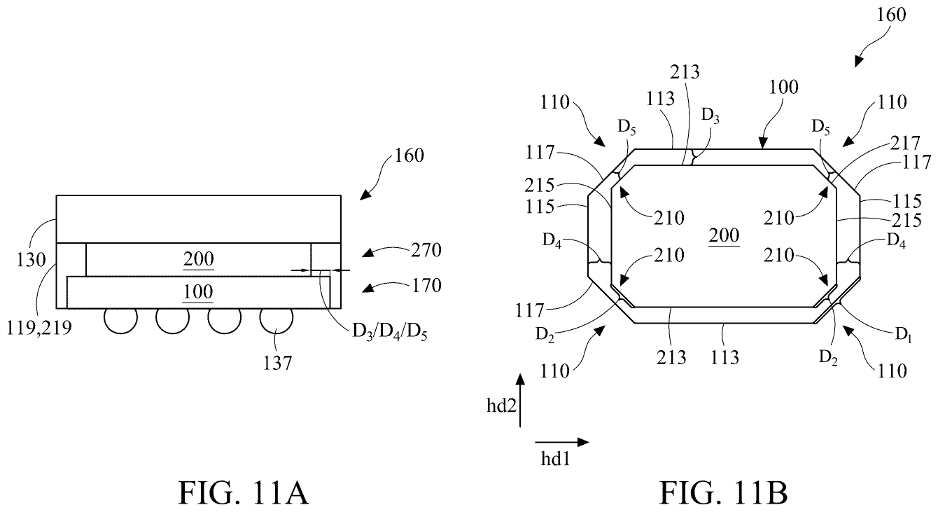

FIGS. 11A-14B illustrate various configurations of a bonded die structure 160 according to various embodiments of the present disclosure. FIG. 11A is a vertical cross-section view of a bonded die structure 160 in accordance with various embodiments of the present disclosure. The bonded die structure 160 shown in FIG. 11A includes a “two-tier” structure including a first tier 170 including one or more first dies 100 and a second tier 270 including one or more second dies 200. Each of the second dies 200 in the second tier 270 is bonded to one or more first dies 100 in the first tier 170. The bonded die structure 160 additionally includes a gap fill dielectric material 119, 219 laterally surrounding the first die(s) 100 and the second die(s) 200 and a second carrier structure 130 located over the gap fill dielectric material 119, 219 and the dies 100, 200. The second tier 270 is located between the first tier 170 and the second carrier structure 130.

FIG. 11B is a top view illustrating the bonded die structure 160 of FIG. 11A. For clarity of illustration, the second carrier structure 130 and the gap fill dielectric material 119, 219 of the bonded die structure 160 of FIG. 11A are not shown in FIG. 11B. Referring to FIG. 11B, the first die 100 and the second die 200 each include a truncated quadrilateral shape including first sides 113, 213 extending along a first horizontal direction hd1, second sides 115, 215 extending along a second horizontal direction hd2 and corner sides 117, 217 extending between the first sides 113, 213 and the second sides 115, 215. In the embodiment of FIG. 11B, the length dimensions D₁ of the corner regions 110 of the first die 100 are greater than the length dimensions D₂ of the corner regions 210 of the second die 200. The offset distances D₅ between the corner sides 117 of the first die 100 and the corner sides 217 of the second die 200 are less than the offset distances D₃ between the first sides 113 the first die 100 and the first sides 213 of the second die 200, and are less than the offset distances D₄ between the second sides 115 of the first die 100 that the second sides 215 of the second die 200. As discussed above, a configuration as shown in FIGS. 11A and 11B may minimize stress accumulation in the corner regions 110 of the first die 100.

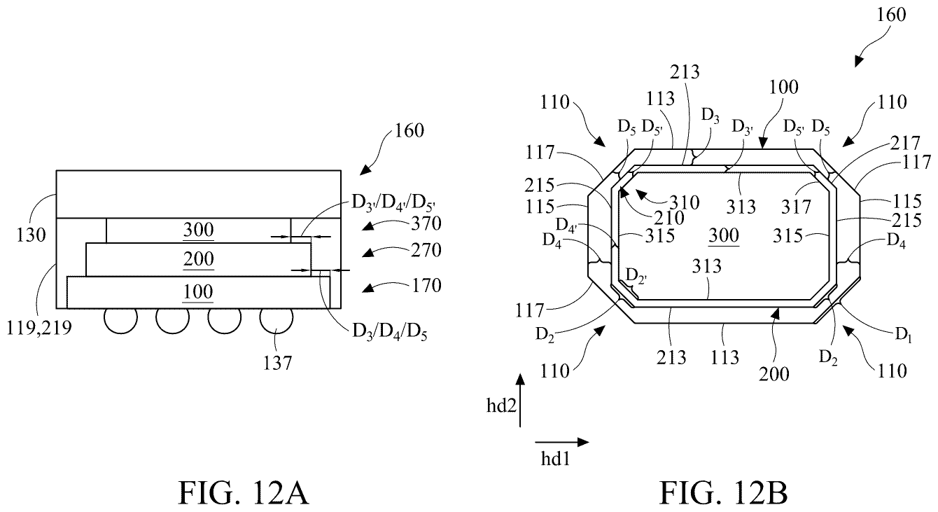

FIG. 12A is a vertical cross-section view of a bonded die structure 160 in accordance with another embodiment of the present disclosure. The bonded die structure 160 shown in FIG. 12A includes a “three-tier” structure including a first tier 170 including one or more first dies 100, a second tier 270 including one or more second dies 200, and a third tier 370 including one or more third dies 300. Each of the third dies 300 in the third tier 370 is bonded to one or more second dies 200 in the second tier 270, and each of the second dies 200 in the second tier 270 is bonded to one or more first dies 100 in the first tier 170. The bonded die structure 160 additionally includes a gap fill dielectric material 119, 219 laterally surrounding the first die(s) 100, the second die(s) 200, and the third dies 300, and a second carrier structure 130 located over the gap fill dielectric material 119, 219 and the dies 100, 200, 300. The second tier 270 is located between the first tier 170 and the third tier 370, and the third tier 370 is located between the second tier 270 and the second carrier structure 130.

FIG. 12B is a top view illustrating the bonded die structure 160 of FIG. 12A. For clarity of illustration, the second carrier structure 130 and the gap fill dielectric material 119, 219 of the bonded die structure 160 of FIG. 12A are not shown in FIG. 12B. Referring to FIG. 12B, configuration of the first tier 170 and the second tier 270 in the bonded die structure 160 of FIG. 12A is identical to the configuration of the first tier 170 and the second tier 270 described above with reference to FIG. 11B. The third die 300 in the third tier 270 includes a truncated quadrilateral shape including first sides 313 extending along the first horizontal direction hd1, second sides 315 extending along the second horizontal direction hd2 and corner sides 317 extending between the first sides 313 and the second sides 315. In the embodiment of FIG. 12B, the length dimensions D₂′ of the corner regions 310 of the third die 300 are less than the length dimensions D₂ of the corner regions 210 of the second die 200. The offset distances D₅′ between the corner sides 217 of the second die 200 and the corner sides 317 of the third die 300 are less than the offset distances D₃′ between the first sides 213 of the second die 200 and the first sides 313 of the third die 300, and less than the offset distances D₄′ between the second sides 215 of the second die 200 and the second sides 315 of the third die 300. A configuration as shown in FIGS. 12A and 12B may minimize stress accumulation in the corner regions 110, 210 of the first die 100 and the second die 200.

Although FIGS. 12A and 12B illustrate a bonded die structure 160 including three tiers 170, 270 and 370, it will be understood that a bonded die structure 160 may include more than three tiers, where each tier includes at least one die bonded to at least one die of the underlying tier. Corner region(s) of the one or more dies in each adjacent tier may have a configuration as described above with reference to FIGS. 12A and 12B.

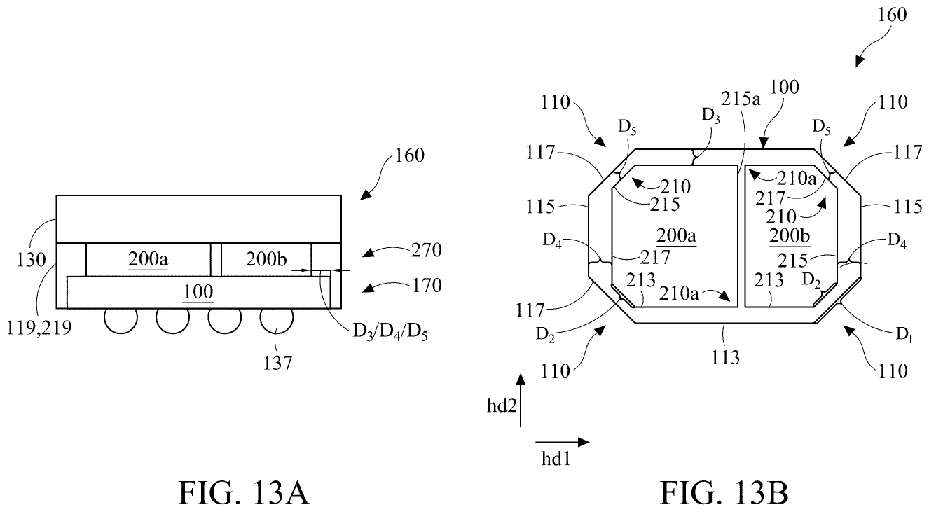

FIG. 13A is a vertical cross-section view of a bonded die structure 160 in accordance with another embodiment of the present disclosure. The bonded die structure 160 shown in FIG. 13A includes a “two-tier” structure including a first tier 170 including a first die 100 and a second tier 270 including a first second die 200a and a second die 200b. In one non-limiting embodiment, the first die 100 may include a logic die, the first second die 200a may include a memory die (e.g., an SRAM die), the second die 200b may include a “dummy” die. Other suitable configurations for the bonded die structure 160 are within the contemplated scope of disclosure. Each of the second dies 200a and 200b in the second tier 270 is bonded to the first die 100 in the first tier 170. The bonded die structure 160 additionally includes a gap fill dielectric material 119, 219 laterally surrounding the first die 100 and each of the second dies 200a and 200b and a second carrier structure 130 located over the gap fill dielectric material 119, 219 and the dies 100, 200a and 200b. The second tier 270 is located between the first tier 170 and the second carrier structure 130.

FIG. 13B is a top view illustrating the bonded die structure 160 of FIG. 13A. For clarity of illustration, the second carrier structure 130 and the gap fill dielectric material 119, 219 of the bonded die structure 160 of FIG. 13A are not shown in FIG. 13B. Referring to FIG. 13B, configuration of the first tier 170 in the bonded die structure 160 of FIG. 13A is identical to the configuration of the first tier 170 described above with reference to FIGS. 11B and 12B. The second tier 270 in the embodiment of FIG. 13B includes a pair of second dies 200a and 200b bonded to the first die 100. Each second die 200a and 200b includes a pair of first sides 213 extending adjacent to the first sides 113 of the first die 100. Each of the second dies 200a and 200b additionally includes a second side 215 (which may be referred to as an “outer” second side 215) extending adjacent to a first side 113 of the first die 100, and another second side 215a (which may be referred to as an “inner” second side 215) that faces toward the inner second side 215a of the other first die 200a and 200b. The corner regions 210 of the second dies 200a and 200b that are adjacent to corresponding corner regions 110 of the first die 100 each include corner sides 217 that are located between the outer second side 215 and the respective first sides 213 of the second die 200a, 200b. The second dies 200a and 200b also include “inner” corner regions 210a between the inner second side 215 and the respective first sides 213 of the second die 200a, 200b. In the embodiment of FIG. 2B, the inner corner regions 210a include edges where the outer second side 215 meets the respective first sides 213 of the second die 200a, 200b. However, in other embodiments, the inner corner regions 210a may have different shapes, and may include corner sides 217 extending diagonally between the inner second side 215 and the first sides 213, as with the outer corner regions 210 of the second dies 200a and 200b as shown in FIG. 13B.

In the embodiment of FIG. 13B, the length dimensions D₁ of the corner regions 110 of the first die 100 are greater than the length dimensions D₂ of the corner regions 210 of the second dies 200a and 200b. The offset distances D₅ between the corner sides 117 of the first die 100 and the corner sides 217 of the second dies 200a and 200b are less than the offset distances D₃ between the first sides 113 the first die 100 and the first sides 213 of the second dies 200a and 200b, and are less than the offset distances D₄ between the second sides 115 of the first die 100 that the second sides 215 of the second dies 200a and 200b. As discussed above, a configuration as shown in FIGS. 11A and 11B may minimize stress accumulation in the corner regions 110 of the first die 100.

Although FIGS. 13A and 13B illustrate an embodiment in which the second tier 270 includes two second dies 200a and 200b, it will be understood that in other embodiments, the second tier 270 may include more than two second dies 200 bonded to the first die 100. The outer corners 210 and sides 213, 215 and 217 of the second dies 200 may have a configuration as illustrated in FIGS. 13A and 13B.

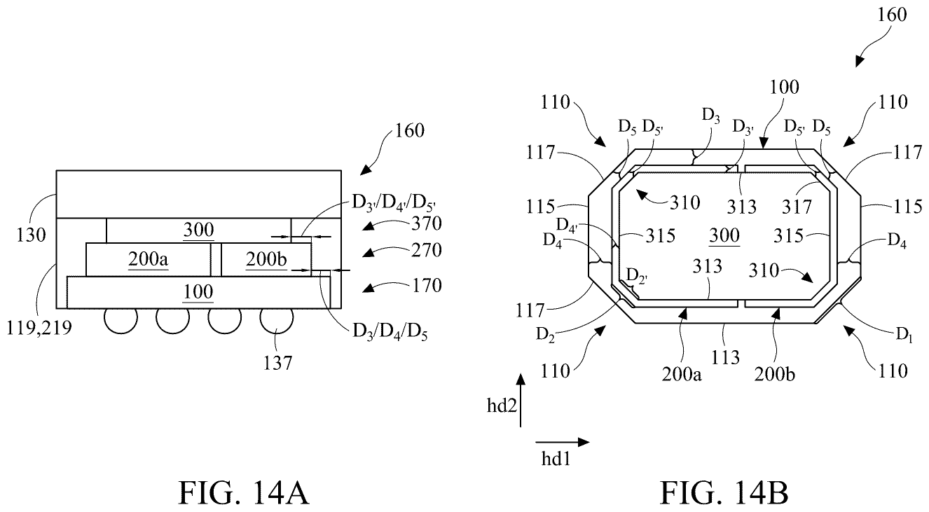

FIG. 14A is a vertical cross-section view of a bonded die structure 160 in accordance with another embodiment of the present disclosure. The bonded die structure 160 shown in FIG. 14A includes a “three-tier” structure including a first tier 170 including a first die 100, a second tier 270 including a first second die 200a and a second die 200b, and a third tier 370 including a third die 300. The third die 300 in the third tier 370 is bonded to the second dies 200a and 200b in the second tier 270, and each of the second dies 200a and 200b in the second tier 270 is bonded to the first die 100 in the first tier 170. In one non-limiting embodiment, the first die 100 may include an input/output (IO) die, the first second die 200a may include a memory die (e.g., an SRAM die), the second die 200b may include a deep trench capacitor (DTC) die, and the third die 300 may include a logic die. Other suitable configurations for the bonded die structure 160 are within the contemplated scope of disclosure. The bonded die structure 160 additionally includes a gap fill dielectric material 119, 219 laterally surrounding the first die 100, the second dies 200a and 200b, and the third die 300, and a second carrier structure 130 located over the gap fill dielectric material 119, 219 and the dies 100, 200a, 200b, 300. The second tier 270 is located between the first tier 170 and the third tier 370, and the third tier 370 is located between the second tier 270 and the second carrier structure 130.

FIG. 14B is a top view illustrating the bonded die structure 160 of FIG. 14A. For clarity of illustration, the second carrier structure 130 and the gap fill dielectric material 119, 219 of the bonded die structure 160 of FIG. 12A are not shown in FIG. 12B. Referring to FIG. 1B, the configuration of the first tier 170 and the second tier 270 in the bonded die structure 160 of FIG. 14A is identical to the configuration of the first tier 170 and the second tier 270 described above with reference to FIG. 13B. The third die 300 in the third tier 270 includes a truncated quadrilateral shape including first sides 313 extending along the first horizontal direction hd1, second sides 315 extending along the second horizontal direction hd2 and corner sides 317 extending between the first sides 313 and the second sides 315. In the embodiment of FIG. 14B, the length dimensions D₂′ of the corner regions 310 of the third die 300 are less than the length dimensions D₂ of the adjacent outer corner regions 210 of the second dies 200a, 200b. The offset distances D₅′ between the corner sides 217 of the second dies 200a and 200b and the corner sides 317 of the third die 300 are less than the offset distances D₃′ between the first sides 213 of the second dies 200a, 200b and the first sides 313 of the third die 300, and less than the offset distances D₄′ between the outer second sides 215 of the second dies 200a, 200b and the second sides 315 of the third die 300. A configuration as shown in FIGS. 14A and 14B may minimize stress accumulation in the corner regions 110, 210 of the first die 100 and the second die 200.

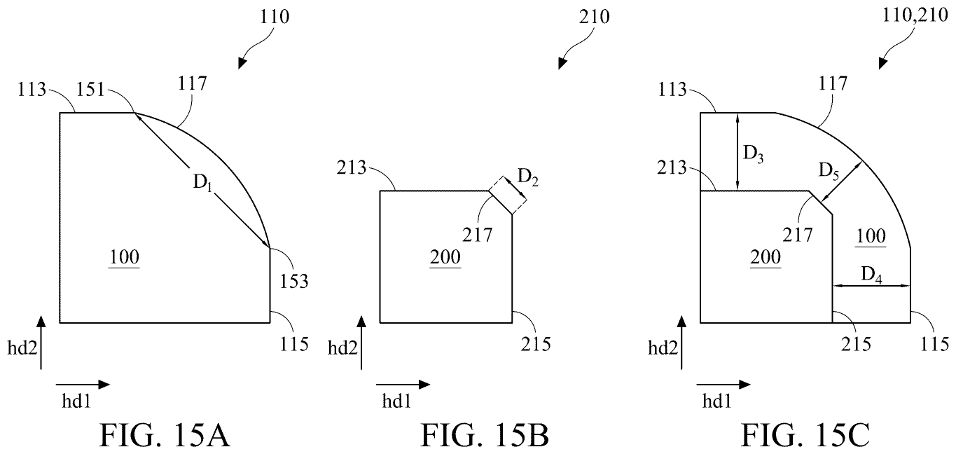

FIG. 15A is a top view of a corner region 110 of a first die 100 according to another embodiment of the present disclosure. FIG. 15B is a top view of a corner region 210 of a second die 200 according to various embodiments of the present disclosure. FIG. 15C is a top view illustrating corner regions 110, 210 of a bonded structure 150 including a second die 200 as shown in FIG. 15B bonded to a first die 100 as shown in FIG. 15A according to various embodiments of the present disclosure. The first die 100 and the second die 200 shown in FIGS. 15A and 15B may be similar to the first die 100 and the second die 200 described above with reference to FIGS. 10A and 10B. Thus, repeated discussion of like features is omitted for brevity. The first die 100 shown in FIG. 15A may differ from the first die 100 shown in FIG. 10A in that one or more of the corner sides 117 of the first die 100 may have an outwardly curved shape between the end point 151 of the first side 113 and the end point 153 of the second side 115 of the first die 100. Thus, the length dimension D₁ of the corner region 110 of the first die 100 shown in FIG. 15A is equal to the length of the line segment extending between the end point 151 of the first side 113 and the end point 153 of the second side 115.

As in the embodiments described above, the length dimension D₁ of the corner region 110 of the first die 100 may be greater than the length dimension D₂ of the corresponding corner region 210 of the second die 200. As shown in FIG. 15C, the offset distance D₅ between the corner side 217 of the second die 200 and the curved corner side 117 of the first die 100 may be less than or equal to the offset distance D₃ between the first side 213 of the second die 200 and the first side 113 of the first die 100, and may be less than or equal to the offset distance D₄ between the second side 213 of the second die 200 and the second side 115 of the first die 100.

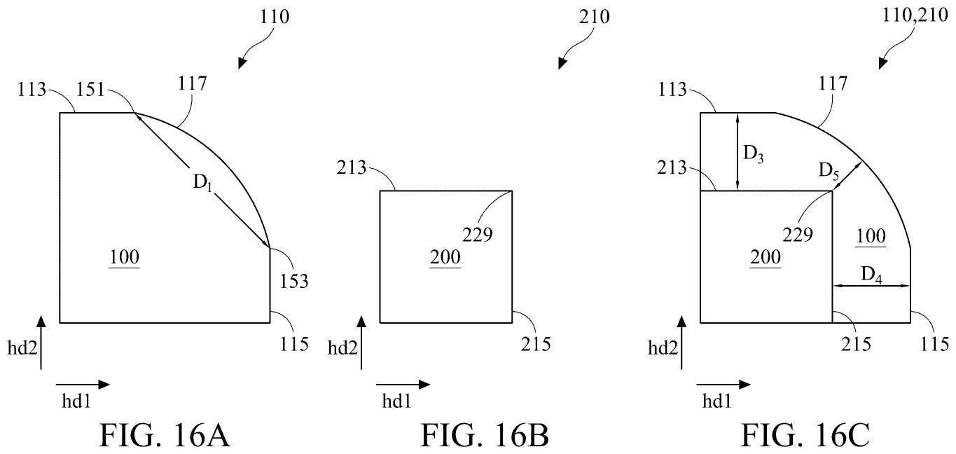

FIG. 16A is a top view of a corner region 110 of a first die 100 according to another embodiment of the present disclosure. FIG. 16B is a top view of a corner region 210 of a second die 200 according to another embodiment of the present disclosure. FIG. 16C is a top view illustrating corner regions 110, 210 of a bonded structure 150 including a second die 200 as shown in FIG. 16B bonded to a first die 100 as shown in FIG. 16A according to various embodiments of the present disclosure. Referring to FIG. 16A, the corner region 110 of the first die 100 may be similar or identical to the corner region 110 of the first die 100 shown in FIG. 15A. That is, the corner side 117 of the first die 100 may have an outwardly curved shape between the end point 151 of the first side 113 and the end point 153 of the second side 115 of the first die 100, such that the length dimension D₁ of the corner region 110 of the first die 100 is equal to the length of the line segment extending between the end point 151 of the first side 113 and the end point 153 of the second side 115. Referring to FIG. 16B, the corner region 210 of the second die 200 may differ from the corner region 210 shown in FIG. 15B in that the first side 213 and the second side 215 of the second die 200 may intersect to form an edge 229 of the second die 200. Thus, in this embodiment, because the first side 213 and the second side 215 of the second die 200 intersect at the edge 229, the length dimension D₂ of the corner region 210 of the second die 200 is essentially zero. As shown in FIG. 16C, the offset distance D₅ between the corner side 217 of the second die 200 (i.e., corresponding to the edge 229 of the second die 200 in this example) and the curved corner side 117 of the first die 100 may be less than or equal to the offset distance D₃ between the first side 213 of the second die 200 and the first side 113 of the first die 100, and may be less than or equal to the offset distance D₄ between the second side 213 of the second die 200 and the second side 115 of the first die 100.

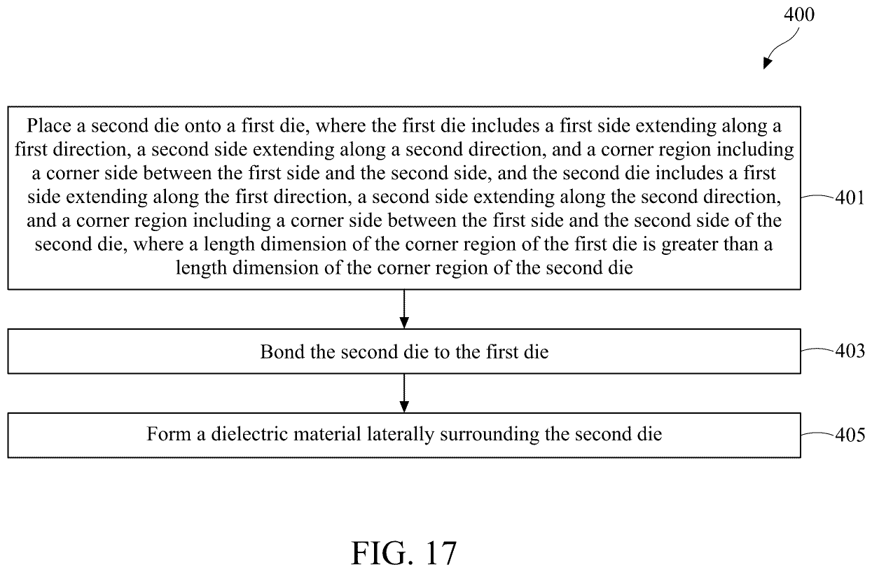

FIG. 17 is a flowchart illustrating a method 400 of fabricating a bonded die structure 160 according to various embodiments of the present disclosure. Referring to FIGS. 4-17, in step 401 of method 400, a second die 200 may be placed onto a first die 100, where the first die 100 includes a first side 113 extending along a first direction hd1, a second side 115 extending along a second direction hd2, and a corner region 110 including a corner side 117 between the first side 113 and the second side 115, and the second die 200 includes a first side 213 extending along the first direction hd1, a second side 215 extending along the second direction hd2, and a corner region 210 including a corner side 217 between the first side 213 and the second side 215 of the second die 200, where a length dimension D₁ of the corner region 110 of the first die 100 is greater than a length dimension D₂ of the corner region 210 of the second die 200.

Referring to FIGS. 4 and 17, in step 403 of method 400, the second die 200 may be bonded to the first die 100. Referring to FIGS. 5 and 17, in step 405 of method 400, a dielectric material 219 may be formed laterally surrounding the second die 200.

Referring to all drawings and according to various embodiments of the present disclosure, a bonded die structure 160 according to various embodiments includes a first die 100 including a first side 113 extending along a first direction hd1, a second side 115 extending along a second direction hd2, and a corner region 110 including a corner side 117 between the first side 113 and the second side 115, a second die 200 bonded to the first die 100, the second die 200 including a first side 213 extending along the first direction hd1, a second side 215 extending along the second direction hd2, and a corner region 210 including a corner side 217 between the first side 213 and the second side 215 of the second die 200, a gap fill dielectric material 119, 219 laterally surrounding the first die 100 and the second die 200, where the second die 200 does not extend beyond the first side 113 or the second side 115 of the first die 100, a first offset distance D₃ between the first side 213 of the second die 200 and the first side 113 of the first die 100 is equal to or greater than zero, a second offset distance D₄ between the second side 215 of the second die 200 and the second side 115 of the first die 100 is equal to or greater than zero, a third offset distance D₅ between the corner side 217 of the second die 200 and the corner side 117 of the first die 100 is less than or equal to at least one of the first offset distance D₃ or the second offset distance D_{4,} and a length dimension D₁ of the corner region 117 of the first die 100 is greater than a length dimension D₂ of the corner region 217 of the second die 200.

In an embodiment, the first offset distance D₃ between the first side 213 of the second die 200 and the first side 113 of the first die 100 is greater than zero, the second offset D₄ distance between the second side 215 of the second die 200 and the second side 115 of the first die 100 is greater than zero, and the third offset distance D₅ between the corner side 217 of the second die 200 and the corner side 117 of the first die 100 is less than the first offset distance D₃ and the second offset distance D_{4.}

In another embodiment, the third offset distance D₅ between the corner side 217 of the second die 200 and the corner side 117 of the first die 100 is between 70% and 90% of the first offset distance D₃ between the first side 213 of the second die 200 and the first side 113 of the first die 100.

In another embodiment, the third offset distance D₅ between the corner side 217 of the second die 200 and the corner side 117 of the first die 100 is between 70% and 90% of the second offset distance D₄ between the second side 215 of the second die 200 and the second side 115 of the first die 100.

In another embodiment, the bonded die structure 150 further includes a carrier structure 130 over the gap fill dielectric material 119, 219, where the second die 200 is located between the carrier structure 130 and the first die 100.

In another embodiment, the first die 100 has a truncated quadrilateral shape including a pair of first sides 113 extending parallel to each other along the first direction hd1, a pair of second sides 115 extending parallel to each other along the second direction hd2, and four corner sides 117 in respective corner regions 110 of the first die 100, where each corner side 117 extends between a first side 113 and a second side 115 of the first die 100.

In another embodiment, the second die 200 has a truncated quadrilateral shape including a pair of first sides 213 extending parallel to each other along the first direction hd1, a pair of second sides 215 extending parallel to each other along the second direction hd2, and four corner sides 217 each extending between a first side 213 and a second side 215 of the second die 200, where a length dimension D₂ of each of the corner sides 217 of the second die 200 is less than a length dimension D₁ of the adjacent corner side 117 of the first die 100.

In another embodiment, multiple second dies 200 are bonded to the first die 100, each second die 200 including a first side 213 extending along the first direction hd1, a second side 215 extending along the second direction hd2, and a corner region 210 including a corner side 217 between the first side 213 and the second side 215 of the second die 200, where none of the second dies 200 extend beyond the first side 113 or the second side 115 of the first die 100, a plurality of the second dies 200 include corner regions 210 adjacent to corner regions 110 of the first die 100, and a length dimension D₁ of corner regions 110 of the first die 100 are greater than length dimensions D₂ of corner regions 210 of multiple second dies 200 that are adjacent to the corner regions 110 of the first die 100.

In another embodiment, at least one of the second dies 200 includes a functional die, and at least one of the second dies 200 includes a non-functional dummy die.

In another embodiment, the corner side 117 of the first die 100 has a curved shape between an end point 151 of the first side 113 of the first die 100 and an end point 153 of the second side 115 of the first die 100, where the length dimension D₁ of the corner region 110 of the first die 100 includes the length of a line segment extending between the end point 151 of the first side 113 of the first die 100 and the end point 153 of the second side 115 of the first die 100.

In another embodiment, the first side 213 of the second die 200 and the second side 215 of the second die 200 meet at an edge 229 that defines the length dimension D₂ of the corner region 210 of the second die 200.

Another embodiment is drawn to a bonded device structure 160 including a first tier 170 including one or more first dies 100, a second tier 270 including one or more second dies 200, where each of the second dies 200 in the second tier 270 is bonded to one or more first dies 100 in the first tier 170, and a gap fill dielectric material 119, 219 laterally surrounding the one or more first dies 100 in the first tier 170 and the one or more second dies 200 in the second tier 270, where an outer corner region 110 of a first die 100 in the first tier 170 includes a first length dimension D₁, a second die 200 of the second tier 270 includes an outer corner region 210 that is adjacent to the outer corner region 110 of the first die 100 in the first tier 170, and a second length dimension D₂ of the outer corner region 210 of the second die 200 in the second tier 270 is less than the first length dimension D₁ of the outer corner region 110 of the first die 100 in the first tier 170.

In one embodiment, the outer corner region 110 of the first die 100 includes a corner side 117 extending in a diagonal direction between a first side 113 of the first die 100 extending in a first horizontal direction hd1 and a second side 115 of the first die 100 extending in a second horizontal direction hd2, the outer corner region 210 of the second die 200 includes a corner side 217 extending in a diagonal direction between a first side 213 of the second die 200 extending in the first horizontal direction hd1 and a second side 215 of the second die 200 extending in the second horizontal direction hd2, and an offset distance D₅ between the corner side 217 of the second die 200 and the corner side 117 of the first die 100 is equal to or less than an offset distance D₃ between the first side 213 of the second die 200 and the first side 113 of the first die 100 and/or an offset distance D₄ between the second side 215 of the second die 200 and the second side 115 of the first die 100.

In another embodiment, the bonded die structure 160 further includes a third tier 370 including one or more third dies 300, where each of the third dies 300 in the third tier 370 is bonded to one or more second dies 200 in the second tier 270, and where the gap fill dielectric material 119, 219 laterally surrounds the one or more third dies 300, and an outer corner region 310 of a third die 300 in the third tier 370 has a third length dimension D₂′, and the third length dimension D₂′ is less than the second length dimension D₂.

In another embodiment, the bonded die structure 160 further includes a carrier structure 130, where the third tier 370 is located between the carrier structure 130 and the second tier 270, and the second tier 270 is located between the third tier 370 and the first tier 170.

In another embodiment, the second tier 270 includes a plurality of second dies 200, where at least one of the second dies 200 includes a non-functional dummy die.

Another embodiment is drawn to a method of fabricating a bonded die structure 160 that includes placing a second die 200 onto a first die 100, where the first die 100 includes a first side 113 extending along a first direction hd1, a second side 115 extending along a second direction hd2, and a corner region 110 including a corner side 117 between the first side 113 and the second side 115, and the second die 200 includes a first side 213 extending along the first direction hd1, a second side 215 extending along the second direction hd2, and a corner region 210 including a corner side 217 between the first side 213 and the second side 215 of the second die 200, where a length dimension D₁ of the corner region of the first die 100 is greater than a length dimension D₂ of the corner region 210 of the second die 200, bonding the second die 200 to the first die 100, and forming a dielectric material 219 laterally surrounding the second die 200.

In one embodiment, the second die 200 is placed on the first die 100 such that the first side 213 of the second die 200 does not extend beyond the first side 113 of the first die 100, and the second side 215 of the second die 200 does not extend beyond the second side 115 of the first die 100, and an offset distance D₅ between a corner side 217 of the second die 200 and a corner side 117 of the first die 100 is less than or equal to at least one of an offset distance D₃ between the first side 213 of the second die 200 and the first side 113 of the first die 100 and an offset distance D₄ between the second side 215 of the second die 200 and the second side 115 of the first die 100.

In another embodiment, the method further includes placing the first die 100 onto a first carrier structure 120, depositing a first dielectric material 119 laterally surrounding the first die 100 prior to placing the second die 200 onto the first die 100 and bonding the second die 200 to the first die 100, depositing a second dielectric material 219 to form the dielectric material 219 laterally surrounding the second die 200, transferring the first die 100, the second die 200, the first dielectric material 119 and the second dielectric material 219 from the first carrier structure 120 to a second carrier structure 130, and performing a dicing process through the first dielectric material 119, the second dielectric material 219, and the second carrier structure 130 to provide the bonded die structure.

In another embodiment, the method further includes placing a third die 300 onto the second die 200, where the third die 300 includes a first side 313 extending along the first direction hd1, a second side 315 extending along the second direction hd2, and a corner region 310 including a corner side 317 between the first side 313 and the second side 315, where the length dimension D₂ of the corner region 210 of the second die 200 is greater than a length dimension D₂′ of the corner region 310 of the third die 300.

The foregoing outlines features of several embodiments so that those skilled in the art may better understand the aspects of this disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of this disclosure, and that they may make various changes, substitutions, and alterations herein without departing from the spirit and scope of the present disclosure.

What is claimed is:

1. A bonded die structure, comprising:
a first die comprising a first side extending along a first direction, a second side extending along a second direction, and a corner region comprising a corner side between the first side and the second side;
a second die bonded to the first die, the second die comprising a first side extending along the first direction, a second side extending along the second direction, and a corner region comprising a corner side between the first side and the second side of the second die; and
a gap fill dielectric material laterally surrounding the first die and the second die, wherein:
the second die does not extend beyond the first side or the second side of the first die,
a first offset distance between the first side of the second die and the first side of the first die is equal to or greater than zero;
a second offset distance between the second side of the second die and the second side of the first die is equal to or greater than zero;
a third offset distance between the corner side of the second die and the corner side of the first die is less than or equal to at least one of the first offset distance or the second offset distance; and
a length dimension of the corner region of the first die is greater than a length dimension of the corner region of the second die.

2. The bonded die structure of claim 1, wherein the first offset distance between the first side of the second die and the first side of the first die greater than zero, the second offset distance between the second side of the second die and the second side of the first die is greater than zero, and the third offset distance between the corner side of the second die and the corner side of the first die is less than the first offset distance and the second offset distance.

3. The bonded die structure of claim 2, wherein the third offset distance between the corner side of the second die and the corner side of the first die is between 70% and 90% of the first offset distance between the first side of the second die and the first side of the first die.

4. The bonded die structure of claim 2, wherein the third offset distance between the corner side of the second die and the corner side of the first die is between 70% and 90% of the second offset distance between the second side of the second die and the second side of the first die.

5. The bonded die structure of claim 1, further comprising a carrier structure over the gap fill dielectric material, wherein the second die is located between the carrier structure and the first die.

6. The bonded die structure of claim 1, wherein the first die comprises a truncated quadrilateral shape comprising a pair of first sides extending parallel to each other along the first direction, a pair of second sides extending parallel to each other along the second direction, and four corner sides in respective corner regions of the first die, wherein each corner side extends between a first side and a second side of the first die.

7. The bonded die structure of claim 6, wherein the second die comprises a truncated quadrilateral shape comprising a pair of first sides extending parallel to each other along the first direction, a pair of second sides extending parallel to each other along the second direction, and four corner sides each extending between a first side and a second side of the second die, wherein a length dimension of each of the corner sides of the second die is less than a length dimension of the adjacent corner side of the first die.

8. The bonded die structure of claim 1, wherein multiple second dies are bonded to the first die, each second die comprising a first side extending along the first direction, a second side extending along the second direction, and a corner region comprising a corner side between the first side and the second side of the second die, wherein none of the second dies extend beyond the first side or the second side of the first die, a plurality of the second dies comprise corner regions adjacent to corner regions of the first die, and a length dimension of corner regions of the first die are greater than length dimensions of corner regions of multiple second dies that are adjacent to the corner regions of the first die.

9. The bonded die structure of claim 8, wherein at least one of the plurality of second dies comprises a functional die, and at least one of the plurality of second dies comprises a non-functional dummy die.

10. The bonded die structure of claim 1, wherein the corner side of the first die comprises a curved shape between an end point of the first side of the first die and an end point of the second side of the first die, wherein a length dimension of the corner region of the first die comprises the length of a line segment extending between the end point of the first side of the first die and the end point of the second side of the first die.

11. The bonded die structure of claim 10, wherein the first side of the second die and the second side of the second die meet at an edge that defines the length dimension of the corner region of the second die.

12. A bonded die structure, comprising:
a first tier comprising one or more first dies;
a second tier comprising one or more second dies, wherein each of the one or more second dies in the second tier is bonded to one or more first dies in the first tier;
and
a gap fill dielectric material laterally surrounding the one or more first dies in the first tier and the one or more second dies in the second tier;
wherein an outer corner region of a first die in the first tier comprises a first length dimension;
a second die of the second tier comprises an outer corner region that is adjacent to the outer corner region of the first die in the first tier, and a second length dimension of the outer corner region of the second die in the second tier is less than the first length dimension of the outer corner region of the first die in the first tier.

13. The bonded die structure of claim 12, wherein the outer corner region of the first die comprises a corner side extending in a diagonal direction between a first side of the first die extending in a first horizontal direction and a second side of the second die extending in a second horizontal direction, and the second die comprises a corner side extending in a diagonal direction between a first side of the second die extending in the first horizontal direction and a second side of the second die extending in the second horizontal direction, and an offset distance between the corner side of the second die and the corner side of the first die is equal to or less than an offset distance between the first side of the second die and the first side of the first die and/or an offset distance between the second side of the second die and the second side of the first die.

14. The bonded die structure of claim 12, further comprising:
a third tier comprising one or more third dies, wherein each of the third dies in the third tier is bonded to one or more second dies in the second tier, wherein:
the gap fill dielectric material laterally surrounds the one or more third dies, and
an outer corner region of a third die in the third tier comprises a third length dimension, and the third length dimension is less than the second length dimension.

15. The bonded die structure of claim 14, further comprising a carrier structure, wherein the third tier is located between the carrier structure and the second tier, and the second tier is located between the third tier and the first tier.

16. The bonded die structure of claim 12, wherein the second tier comprises a plurality of second dies, wherein at least one of the plurality of second dies comprises a non-functional dummy die.

17. A method of fabricating a bonded die structure, comprising:
placing a second die onto a first die, wherein the first die comprises a first side extending along a first direction, a second side extending along a second direction, and a corner region comprising a corner side between the first side and the second side, and the second die comprises a first side extending along the first direction, a second side extending along the second direction, and a corner region comprising a corner side between the first side and the second side of the second die, wherein a length dimension of the corner region of the first die is greater than a length dimension of the corner region of the second die;
bonding the second die to the first die; and
forming a dielectric material laterally surrounding the second die.

18. The method of claim 17, wherein the second die is placed on the first die such that the first side of the second die does not extend beyond the first side of the first die, and the second side of the second die does not extend beyond the second side of the first die, and an offset distance between a corner side of the second die and a corner side of the first die is less than or equal to at least one of an offset distance between the first side of the second die and the first side of the first die and an offset distance between the second side of the second die and the second side of the first die.

19. The method of claim 18, further comprising:
placing the first die onto a first carrier structure;
depositing a first dielectric material laterally surrounding the first die prior to placing the second die onto the first die and bonding the second die to the first die;
depositing a second dielectric material to form the dielectric material laterally surrounding the second die;
transferring the first die, the second die, the first dielectric material and the second dielectric material from the first carrier structure to a second carrier structure;
and
performing a dicing process through the first dielectric material, the second dielectric material, and the second carrier structure to provide the bonded die structure.

20. The method of claim 17, wherein the method further comprises placing a third die onto the second die, wherein the third die comprises a first side extending along the first direction, a second side extending along the second direction, and a corner region comprising a corner side between the first side and the second side, wherein the length dimension of the corner region of the second die is greater than a length dimension of the corner region of the third die.
